(19) United States
(12) Patent Application Publication
(10) Pub. No.: US 2008/0002365 A1
(43) Pub. Date: Jan. 3, 2008

(54) Socket enabled cooling of in-substrate voltage regulator

(76) Inventor: Ashish Gupta, Chandler, AZ (US)

Correspondence Address: INTEL CORPORATION;c/o INTELLEVATE, LLC, P.O. BOX 52050, MINNEAPOLIS, MN, 55402, US

(21) Appl. No.: 11/479,632

(22) Filed: Jun. 29, 2006

(51) Int. Cl. H05K 7/20

(52) U.S. Cl. 361/700

(57) ABSTRACT

In some embodiments, socket enabled cooling of in-substrate voltage regulator is presented. In this regard, a socket is introduced having a socket body with a substantially central cavity, a plurality of contacts through the socket body arranged in a substantially square pattern around the cavity, and an integrated heat spreader substantially covering the cavity. Other embodiments are also disclosed and claimed.

### FIELD OF THE INVENTION

Embodiments of the present invention generally relate to the field of integrated circuit package cooling methods, and, more particularly to socket enabled cooling of in-substrate voltage regulator.

### BACKGROUND OF THE INVENTION

The demand for small form-factor, high-speed computing devices has led to placing components such as voltage regulators on the substrate of an integrated circuit package. A voltage regulator can produce a significant amount of heat that could impact the performance and reliability of the integrated circuit package.

### BRIEF DESCRIPTION OF THE DRAWINGS

The present invention is illustrated by way of example and not limitation in the figures of the accompanying drawings in which like references indicate similar elements, and in which:

FIG. 1 is a graphical illustration of a cross-sectional view of socket enabled cooling of in-substrate voltage regulator, in accordance with one example embodiment of the invention;

FIG. 2 is a graphical illustration of a cross-sectional view of socket enabled cooling of in-substrate voltage regulator, in accordance with one example embodiment of the invention;

FIG. 3 is a graphical illustration of a cross-sectional view of socket enabled cooling of in-substrate voltage regulator, in accordance with one example embodiment of the invention; and

FIG. 4 is a block diagram of an example electronic appliance suitable for implementing socket enabled cooling of in-substrate voltage regulator, in accordance with one example embodiment of the invention.

### DETAILED DESCRIPTION

In the following description, for purposes of explanation, numerous specific details are set forth in order to provide a thorough understanding of the invention. It will be apparent, however, to one skilled in the art that embodiments of the invention can be practiced without these specific details. In other instances, structures and devices are shown in block diagram form in order to avoid obscuring the invention.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments.

FIG. 1 is a graphical illustration of a cross-sectional view of socket enabled cooling of in-substrate voltage regulator, in accordance with one example embodiment of the invention. In accordance with the illustrated example embodiment, electronic device 100 includes one or more of socket body 102, socket contacts 104, integrated heat spreader 106, die 108, substrate 110, in-substrate voltage regulator 112, die heat spreader 114, heat sink 116, and printed circuit board 118.

Socket body 102 represents a material such as plastic that provides mechanical support and attachment for an integrated circuit package and includes socket contacts 104 to electrically couple the integrated circuit package with traces and other components (not shown) on printed circuit board 118. In one embodiment, socket body 102 is a land grid array (LGA) socket with socket contacts 104 arranged in a square pattern around a central cavity.

Integrated heat spreader 106 may cover a cavity in socket body 102 such that it can contact in-substrate voltage regulator 112 when the associated integrated circuit package is inserted in socket body 102. Integrated heat spreader 106 may be made of copper, aluminum or any other metal or metal alloy that would be suitable for spreading heat. Integrated heat spreader 106 may be L-shaped with one end attached to socket body 102 and the other end floating over the cavity, or U-shaped with two ends attached to socket body 102 on opposite sides of the cavity, or basket-shaped with four sides attached to socket body 102 and a flat surface that covers the cavity, or any other shape that allows integrated heat spreader 106 to attach to socket body 102 and provide a heat spreading surface to in-substrate voltage regulator 112.

In-substrate voltage regulator 112 may contact internal heat spreader 106 directly or indirectly through a thermal interface material designed to promote adhesion and heat transfer.

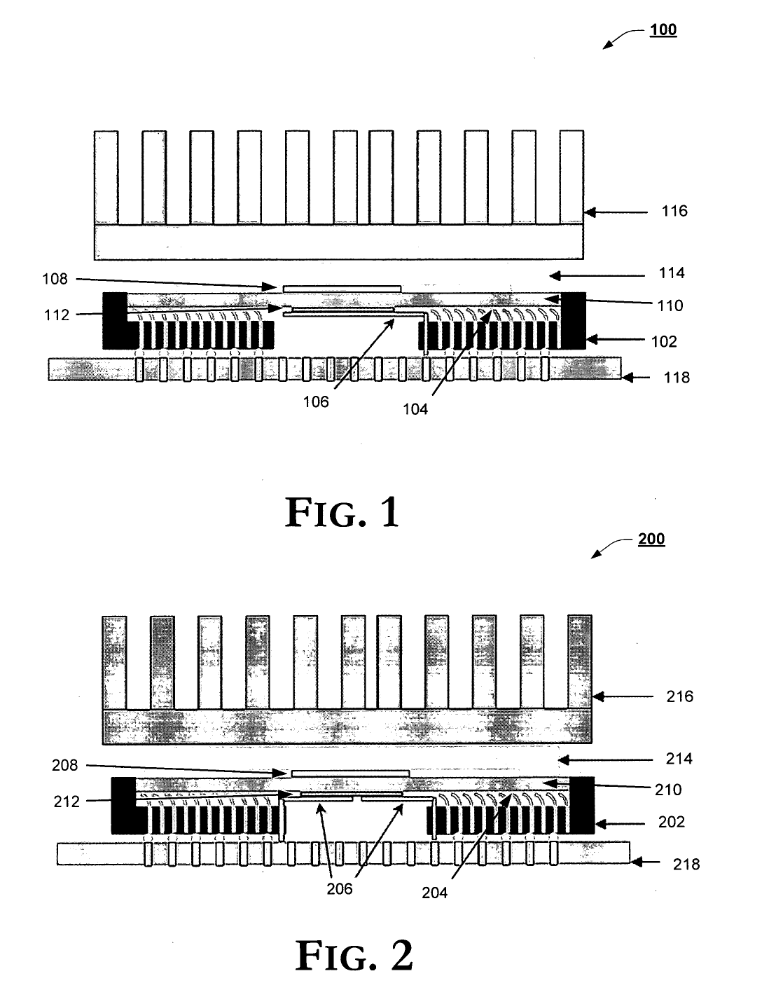

FIG. 2 is a graphical illustration of a cross-sectional view of socket enabled cooling of in-substrate voltage regulator, in accordance with one example embodiment of the invention. As shown, electronic device 200 includes one or more of socket body 202, socket contacts 204, integrated heat spreader 206, die 208, substrate 210, in-substrate voltage regulator 212, die heat spreader 214, heat sink 216, and printed circuit board 218.

In one embodiment, integrated heat spreader 206 is made up of two or more separate pieces which may be of various shapes and materials which spread heat from in-substrate voltage regulator 212.

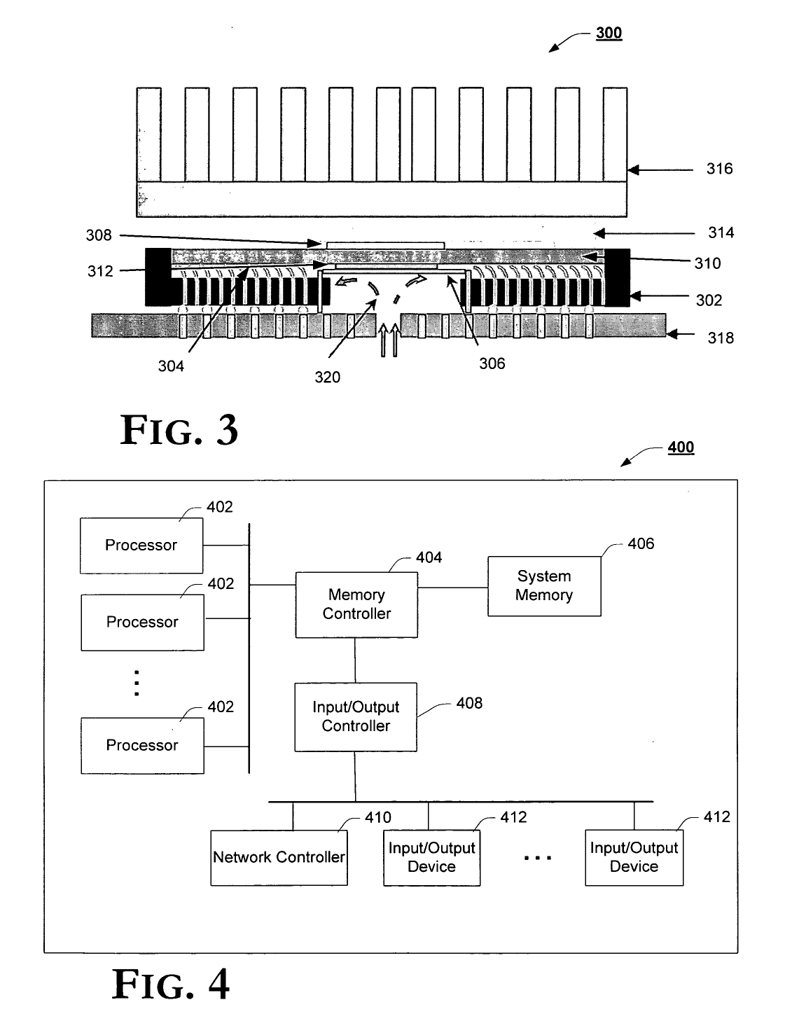

FIG. 3 is a graphical illustration of a cross-sectional view of socket enabled cooling of in-substrate voltage regulator, in accordance with one example embodiment of the invention. As shown, electronic device 300 includes one or more of socket body 302, socket contacts 304, integrated heat spreader 306, die 308, substrate 310, in-substrate voltage regulator 312, die heat spreader 314, heat sink 316, printed circuit board 318, and airflow 320.

In one embodiment, printed circuit board 318 may have a hole through which airflow 320 can reach integrated heat spreader 306 and provide convection. Additionally fans, heat sinks, heat pipes and the like can be included to further dissipate heat from integrated heat spreader 306.

FIG. 4 is a block diagram of an example electronic appliance suitable for implementing socket enabled cooling of in-substrate voltage regulator, in accordance with one example embodiment of the invention. Electronic appliance 400 is intended to represent any of a wide variety of traditional and non-traditional electronic appliances, laptops, desktops, cell phones, wireless communication subscriber units, wireless communication telephony infrastructure elements, personal digital assistants, set-top boxes, or any electric appliance that would benefit from the teachings of the present invention. In accordance with the illustrated example embodiment, electronic appliance 400 may include one or more of processor(s) 402, memory controller 404, system memory 406, input/output controller 408, network controller 410, and input/output device(s) 412 coupled as shown in FIG. 5. Processor(s) 402, or other integrated circuit components of electronic appliance 400, may be housed in a socket including an integrated heat spreader described previously as an embodiment of the present invention.

Processor(s) 402 may represent any of a wide variety of control logic including, but not limited to one or more of a microprocessor, a programmable logic device (PLD), programmable logic array (PLA), application specific integrated circuit (ASIC), a microcontroller, and the like, although the present invention is not limited in this respect. In one embodiment, processors(s) 402 are Intel® compatible processors. Processor(s) 402 may have an instruction set containing a plurality of machine level instructions that may be invoked, for example by an application or operating system.

Memory controller 404 may represent any type of chipset or control logic that interfaces system memory 406 with the other components of electronic appliance 400. In one embodiment, the connection between processor(s) 402 and memory controller 404 may be referred to as a front-side bus. In another embodiment, memory controller 404 may be referred to as a north bridge.

System memory 406 may represent any type of memory device(s) used to store data and instructions that may have been or will be used by processor(s) 402. Typically, though the invention is not limited in this respect, system memory 406 will consist of dynamic random access memory (DRAM). In one embodiment, system memory 406 may consist of Rambus DRAM (RDRAM). In another embodiment, system memory 406 may consist of double data rate synchronous DRAM (DDRSDRAM).

Input/output (I/O) controller 408 may represent any type of chipset or control logic that interfaces I/O device(s) 412 with the other components of electronic appliance 400. In one embodiment, I/O controller 408 may be referred to as a south bridge. In another embodiment, I/O controller 408 may comply with the Peripheral Component Interconnect (PCI) Express™ Base Specification, Revision 1.0a, PCI Special Interest Group, released Apr. 15, 2003.

Network controller 410 may represent any type of device that allows electronic appliance 400 to communicate with other electronic appliances or devices. In one embodiment, network controller 410 may comply with a The Institute of Electrical and Electronics Engineers, Inc. (IEEE) 802.11b standard (approved Sep. 16, 1999, supplement to ANSI/IEEE Std 802.11, 1999 Edition). In another embodiment, network controller 410 may be an Ethernet network interface card.

Input/output (I/O) device(s) 412 may represent any type of device, peripheral or component that provides input to or processes output from electronic appliance 400.

In the description above, for the purposes of explanation, numerous specific details are set forth in order to provide a thorough understanding of the present invention. It will be apparent, however, to one skilled in the art that the present invention may be practiced without some of these specific details. In other instances, well-known structures and devices are shown in block diagram form.

Many of the methods are described in their most basic form but operations can be added to or deleted from any of the methods and information can be added or subtracted from any of the described messages without departing from the basic scope of the present invention. Any number of variations of the inventive concept is anticipated within the scope and spirit of the present invention. In this regard, the particular illustrated example embodiments are not provided to limit the invention but merely to illustrate it. Thus, the scope of the present invention is not to be determined by the specific examples provided above but only by the plain language of the following claims.

What is claimed is:

1. An apparatus comprising:
a socket body with a substantially central cavity;
a plurality of contacts through the socket body arranged in a substantially square pattern around the cavity; and
an integrated heat spreader substantially covering the cavity.

2. The apparatus of claim 1, wherein the integrated heat spreader comprises copper.

3. The apparatus of claim 1, wherein the integrated heat spreader comprises aluminum.

4. The apparatus of claim 1, wherein the integrated heat spreader comprises a metal alloy.

5. The apparatus of claim 1, wherein the integrated heat spreader comprises one or more L-shaped pieces.

6. The apparatus of claim 1, wherein the integrated heat spreader comprises a U-shaped piece.

7. The apparatus of claim 1, wherein the integrated heat spreader comprises a basket-shaped piece.

8. An apparatus comprising:
a printed circuit board; and
a socket coupled with the printed circuit board, the socket including a socket body and an integrated heat spreader coupled with the socket body to spread heat from an in-substrate voltage regulator.

9. The apparatus of claim 8, further comprising a hole in the printed circuit board to provide airflow to a surface of the integrated heat spreader.

10. The apparatus of claim 8, wherein the integrated heat spreader comprises a material chosen from the group consisting of: copper, aluminum, and metal alloys.

11. The apparatus of claim 8, wherein the integrated heat spreader comprises a shape chosen from the group consisting of: L-shaped, U-shaped, and basket-shaped.

12. An electronic appliance comprising:
a network controller;
a system memory;
a processor, wherein the processor includes an in-substrate voltage regulator; and
a processor socket coupled with the processor, wherein the processor socket includes a socket body, socket contacts, and an integrated heat spreader.

13. The electronic appliance of claim 12, further comprising thermal interface material between the in-substrate voltage regulator and the integrated heat spreader.

14. The electronic appliance of claim 12, further comprising a heat pipe coupled with the integrated heat spreader.

15. The electronic appliance of claim 12, further comprising means for circulating air over the integrated heat spreader.

16. A method comprising:
seating an integrated circuit package including an in-substrate voltage regulator in a socket including an integrated heat spreader designed to spread heat from the in-substrate voltage regulator.

17. The method of claim 16, further comprising applying thermal interface material to the integrated heat spreader.

18. The method of claim 16, further comprising applying thermal interface material to the in-substrate voltage regulator.

19. The method of claim 16, further comprising installing means for circulating air over the integrated heat spreader.

20. The method of claim 16, further comprising installing a heat pipe coupled with the integrated heat spreader.
